(19) United States
(12) Patent Application Publication
(10) Pub. No.: US 2025/0309073 A1
(43) Pub. Date: Oct. 2, 2025

(54) ELECTRONIC DEVICE

(71) Applicant: Advanced Semiconductor Engineering, Inc., Kaohsiung (TW)

(72) Inventor: Yung-Li LU, Kaohsiung (TW)

(73) Assignee: Advanced Semiconductor Engineering, Inc., Kaohsiung (TW)

(21) Appl. No.: 18/622,792

(22) Filed: Mar. 29, 2024

(51) Int. Cl. H01L 23/498; H01L 23/00; H01L 23/31

(52) U.S. Cl. CPC H01L 23/49805; H01L 23/49833; H01L 24/06; H01L 24/13; H01L 24/16; H01L 24/24; H01L 23/3107; H01L 23/315; H01L 24/17; H01L 24/73; H01L 24/81; H01L 24/82; H01L 2224/06189; H01L 2224/13111; H01L 2224/13139; H01L 2224/13144; H01L 2224/16013; H01L 2224/16059; H01L 2224/16155; H01L 2224/16227; H01L 2224/1703; H01L 2224/17181; H01L 2224/17183; H01L 2224/215; H01L 2224/24101; H01L 2224/24155; H01L 2224/73259; H01L 2224/81001; H01L 2224/811; H01L 2224/82101; H01L 2924/01013; H01L 2924/01022; H01L 2924/01029; H01L 2924/01047; H01L 2924/014; H01L 2924/04941

(57) ABSTRACT

The present disclosure provides an electronic device. The electronic device includes an electronic component configured to laterally receive a power and configured to non-laterally transmit a signal. The electronic component includes an integrated circuit layer configured to receive the power.

### BACKGROUND

### 1. Field of the Disclosure

The present disclosure generally relates to an electronic device, and more particularly to an electronic device including a power supply element with a lateral electrical interconnection.

### 2. Description of the Related Art

Traditional integrated circuit (IC) design involves placing power and signal in the front side and backside of the IC, causing signal interference due to power influence, resulting in lower success rate and unnecessary coupling effects. In order to achieve optimal IC performance, a backside power delivery chip has been developed to address these issues. However, such approach still involves power and I/O entering and exiting the chip from the same side, leading to the aforementioned problems in high I/O chip requirements.

### SUMMARY

In some embodiments, an electronic device includes an electronic component configured to laterally receive a power and configured to non-laterally transmit a signal. The electronic component includes an integrated circuit layer configured to receive the power.

In some embodiments, an electronic device includes an integrated circuit component and a power supply element. The integrated circuit component has a lateral surface. The power supply element is disposed adjacent to the integrated circuit component and has a first lateral surface. The lateral surface and the first lateral surface collectively build a power path.

In some embodiments, an electronic device includes an electronic component. The electronic component has a lateral side, an integrated circuit layer, and a power delivery network (PDN). The PDN is disposed over the integrated circuit layer. A portion of the PDN is exposed by the lateral side and is configured to receive a power.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 is a cross-sectional view of an electronic device, in accordance with an embodiment of the present disclosure.

FIG. 2 is a cross-sectional view of an electronic device, in accordance with an embodiment of the present disclosure.

FIG. 3A is a cross-sectional view of an electronic device, in accordance with an embodiment of the present disclosure.

FIG. 3B is a top view of the electronic device as shown in FIG. 3A, in accordance with an embodiment of the present disclosure.

FIG. 3C is a side view of the electronic device as shown in FIG. 3A, in accordance with an embodiment of the present disclosure.

FIG. 4 is a cross-sectional view of an electronic device, in accordance with an embodiment of the present disclosure.

FIG. 5 is a cross-sectional view of an electronic device, in accordance with an embodiment of the present disclosure.

FIG. 6A is a cross-sectional view of an electronic device, in accordance with an embodiment of the present disclosure.

FIG. 6B is a top view of the electronic device as shown in FIG. 6A, in accordance with an embodiment of the present disclosure.

FIG. 7 is a top view of an electronic device, in accordance with an embodiment of the present disclosure.

FIG. 8 is a cross-sectional view of an electronic device, in accordance with an embodiment of the present disclosure.

FIG. 9A, FIG. 9B, and FIG. 9C illustrate various stages of an example of a method for manufacturing an electronic device according to some embodiments of the present disclosure.

FIG. 10A, FIG. 10B, and FIG. 10C illustrate various stages of an example of a method for manufacturing an electronic device according to some embodiments of the present disclosure.

FIG. 11A and FIG. 11B illustrate various stages of an example of a method for manufacturing an electronic device according to some embodiments of the present disclosure.

FIG. 12A and FIG. 12B illustrate various stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

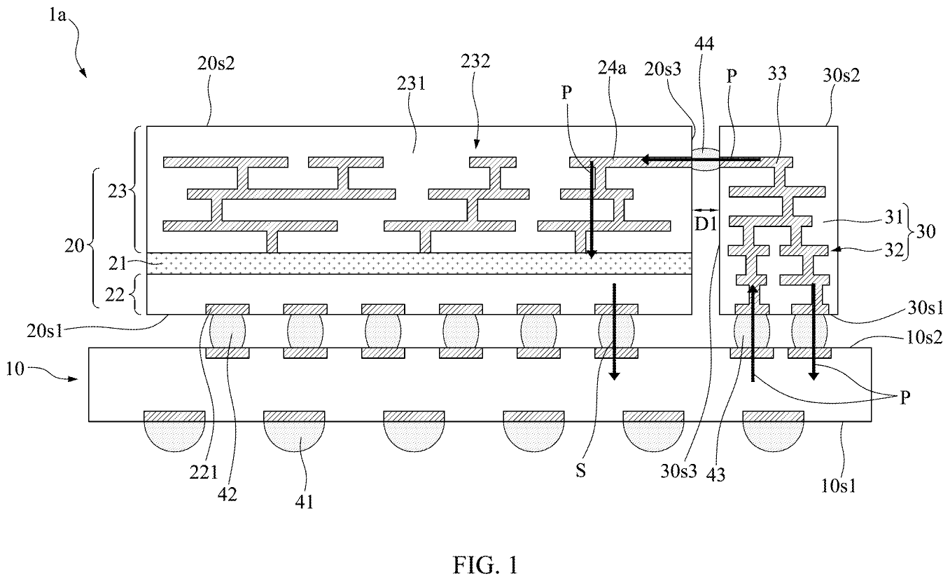

FIG. 1 is a cross-sectional view of an electronic device 1a, in accordance with an embodiment of the present disclosure. In some embodiments, the electronic device 1a may include a carrier 10, an electronic component 20, and a conductive structure 30.

The carrier 10 (or a circuit structure) may include a system board, a main board, a main printed circuit board (PCB) or other suitable carriers. The carrier 10 may include an interconnection structure, such as a redistribution layer (RDL), a circuit layer, a conductive trace, a conductive via, or other suitable elements. The interconnection structure may provide a non-lateral signal path(s) and/or a lateral power path(s) for other components electrically connected to the carrier 10. For example, the carrier 10 may facilitate and allow communications among the components mounted over it. In some embodiments, the carrier 10 may receive and/or transmit a signal S (or a non-power signal), such as an input/output I/O signal, data signal, analog signal, or the like. In some embodiments, the carrier 10 may receive and/or transmit power. In some embodiments, the carrier 10 may receive and/or transmit power P (or a power signal) from and/or to the conductive structure 30. The carrier 10 may have a surface 10s1 (or a lower surface) and a surface 10s2 (or an upper surface) opposite to the surface 10s1. The carrier 10 may include conductive pads (not denoted) adjacent to the surfaces 10s1 and 10s2.

In some embodiments, the electronic component 20 (or integrated circuit component) may be disposed on or over the surface 10s2 of the carrier 10. The electronic component 20 may include a logic die (e.g., an application-specific IC (ASIC), application processor (AP), system-on-a-chip (SoC), central processing unit (CPU), graphics processing unit (GPU), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies) or other suitable active components. In some embodiments, the electronic component 20 may include a passive device, such as an inductor, a resistor, and/or a capacitor. The electronic component 20 may have a surface 20s1 (or a lower surface), a surface 20s2 (or an upper surface) opposite to the surface 20s1, and a surface 20s3 (or a lateral surface) extending between the surfaces 20s1 and 20s2. In some embodiments, the surface 20s1 of the electronic component 20 may be configured to transmit a signal (e.g., the signal S). The surface 20s1 may also be referred to as an active surface or a front side surface. The surface 20s2 may also be referred to as a passive surface or a backside surface. The surface 20s3 may face the conductive structure 30. In some embodiments, the surface 20s3 of the electronic component 20 may be configured to receive and/or transmit power (e.g., the power P). In some embodiments, the electronic component 20 may include an integrated circuit (IC) layer 21, a redistribution structure 22, and a redistribution structure 23.

The IC layer 21 may be adjacent to or abut the surface 20s1 of the electronic component 20. The IC layer 21 may include one or more ICs configured to generate and/or process a signal (e.g., the signal S). The IC layer 21 may be configured to receive power (e.g., the power P). The ICs may be formed or disposed within a semiconductor substrate (e.g., a silicon substrate, a gallium nitride substrate, or other suitable substrates).

The redistribution structure 22 (or a front redistribution structure) may be disposed adjacent to the surface 20s1 of the electronic component 20. The redistribution structure 22 may include conductive traces (not shown) and/or conductive vias (not shown) disposed on or within dielectric layers. The redistribution structure 22 may include conductive pads 221 exposed by the surface 20s1 of the electronic component 20. The redistribution structure 22 may be configured to transmit a signal (e.g., the signal S).

The redistribution structure 23 (or a backside redistribution structure) may be disposed adjacent to the surface 20s2 of the electronic component 20. The thickness of the redistribution structure 23 may be greater than that of the redistribution structure 22. The redistribution structure 23 may include a dielectric structure 231 and a power delivery network (PDN) 232. The dielectric structure 231 may include, for example, polyimide (PI), polyimide-isoindoloquinazolinedione (PIQ), polybenzoxazole (PBO), benzocyclobutene (BCB), or other suitable materials. The PDN 232 may include conductive traces and/or conductive vias disposed within the dielectric structure 231.

In some embodiments, the PDN 232 may include an electrical connection 24a (or a laterally electrical connection), which is configured to receive and/or transmit power (e.g., the power P). In some embodiments, the electrical connection 24a may be exposed by the surface 20s3 of the electronic component 20. The electrical connection 24a may include a conductive trace or a conductive via which is tapered toward the surface 20s1 of the electronic component 20.

In some embodiments, the top of the PDN 232 (e.g., the topmost layer of the conductive trace or conductive via) may be covered by the dielectric structure 231; the top of the PDN 232 may not be exposed by the surface 20s2 of the electronic component 20. In this embodiment, no power and/or no signal is transmitted through the surface 20s2 of the electronic component 20. However, the present disclosure is not intended to be limiting. In other embodiments, the surface 20s2 of the electronic component 20 may be configured to receive and/or transmit a signal or power. In this embodiment, conductive pads may abut and be exposed by the surface 20s2 of the electronic component 20.

In some embodiments, the conductive structure 30 (or power supply element) may be disposed on or over the surface 10s2 of the carrier 10. In some embodiments, the electronic component 20 and the conductive structure 30 may be arranged side by side. In some embodiments, the conductive structure 30 may be configured to receive and/or transmit power (e.g., the power P) from and/or to the carrier 10. In some embodiments, the conductive structure 30 may be configured to receive and/or transmit power (e.g., the power P) from and/or toward the electronic component 20. The conductive structure 30 may include a dielectric structure 31 and conductive layers 32. In some embodiments, the conductive structure 30 may include an interposer (e.g., substrate interposer), a power management integrated circuit (PMIC) die, or other suitable conductive structures. The conductive structure 30 may have a surface 30s1 (or a lower surface), a surface 30s2 (or an upper surface) opposite to the surface 30s1, and a surface 30s3 (or a lateral surface) extending between the surfaces 30s1 and 30s2. In some embodiments, the surface 30s1 may be configured to receive and/or transmit power (e.g., the power P). In some embodiments, the surface 30s1 of the conductive structure 30 may be at a level (or elevation) substantially the same as that of the surface 20s1 of the electronic component 20 with respect to the surface 10s2 of the carrier 10. In some embodiments, the surface 30s2 of the conductive structure 30 may be at a level (or elevation) substantially the same as that of the surface 20s2 of the electronic component 20 with respect to the surface 10s2 of the carrier 10. In other embodiments, the surface 30s2 of the conductive structure 30 may be at a level (or elevation) different from that of the surface 20s2 of the electronic component 20 with respect to the surface 10s2 of the carrier 10. The surface 30s3 of the conductive structure 30 may face the surface 20s3 of the electronic component 20. In some embodiments, the electronic component 20 and the conductive structure 30 may define a distance D1. The distance D1 may range between about 2 μm and about 30 μm, such as 2 μm, 5 μm, 10 μm, 15 μm, or 30 μm.

The dielectric structure 31 may include, for example, PI, PIQ, PBO, BCB, or other suitable materials. The conductive layers 32 may include conductive traces and/or conductive vias disposed within the dielectric structure 31.

In some embodiments, the dielectric structure 31 may include an electrical connection 33 (or a laterally electrical connection), which is configured to receive and/or transmit power (e.g., the power P). In some embodiments, the electrical connection 33 may be exposed by the surface 30s3 of the conductive structure 30. The electrical connection 33 may include a conductive trace or a conductive via which is tapered toward the surface 30s1 of the conductive structure 30. In some embodiments, the electrical connection 24a may be substantially horizontally aligned with the electrical connection 33.

The electronic device 1a may include electrical connections 41, 42, and 43. The electrical connection 41 may be disposed on or under the surface 10s1 of the carrier 10. The electrical connection 41 may be configured to electrically connect the electronic device 1a and an external device (not shown). The electrical connection 42 may be disposed between and electrically connect the carrier 10 and the electronic component 20. The electrical connection 43 may be disposed between and electrically connect the carrier 10 and the conductive structure 30. The electrical connections 41, 42, and 43 may include a solder material (or solder element), such as alloys of gold and tin solder or alloys of silver and tin solder. In some embodiments, the pitch of the electrical connections 41 may be greater than that of the electrical connections 42. In some embodiments, the pitch of the electrical connections 41 may be greater than that of the electrical connections 43.

In some embodiments, the electronic device 1a may include a power connector 44 (or conductive element or electrical connection or electrical contact). In some embodiments, the power connector 44 may be configured to electrically connect the electronic component 20 and the conductive structure 30. In some embodiments, the power connector 44 may be configured to receive and/or transmit power (e.g., the power P) between the electronic component 20 and the conductive structure 30. In some embodiments, the power connector 44 may be disposed between the electronic component 20 and the conductive structure 30. In some embodiments, the power connector 44 may be disposed on the surface 20s3 of the electronic component 20. In some embodiments, the power connector 44 may be disposed on the surface 30s3 of the conductive structure 30. In some embodiments, the power connector 44 may overhang the electronic component 20. In some embodiments, the power connector 44 may include a conductive material. In some embodiments, the power connector 44 may include a solder material (or solder element), such as alloys of gold and tin solder or alloys of silver and tin solder. In some embodiments, a dimension (e.g., size) of the power connector 44 may be less than that of the electrical connection 43. The dimension of the power connector 44 may depend on the distance D1. In this embodiment, the power connector 44 may be formed by the flow of solder material into the gap between the electronic component 20 and the conductive structure 30. As a result, the profile of the power connector 44 may be different from that of the electrical connections 41, 42, and 43. As shown in FIG. 1, the arrow may indicate the power path of power P. In some embodiments, the power connector 44 may be included in a part of the power path. In some embodiments, the power path may flow past or pass past the surface 20s3 of the electronic component 20. In some embodiments, the elevation of the power connector 44 may be greater (or higher) than that of the IC layer 21.

In a comparative example, power may be transmitted to an electronic component through a backside surface of the electronic component. In this condition, a conductive wire or interposer is vertically over the backside surface, which increases the overall thickness of the electronic device. In this embodiment, the power connector 44 is used to laterally or horizontally connect the electronic component 20 and the conductive structure 30. Further, the front surface (e.g., surface 20s1) of the electronic component 20 may be configured to transmit signal to meet the performance requirements of the electronic device 1a. Thus, the electronic device 1a has a smaller thickness in comparison with a comparative example, while maintaining better performance.

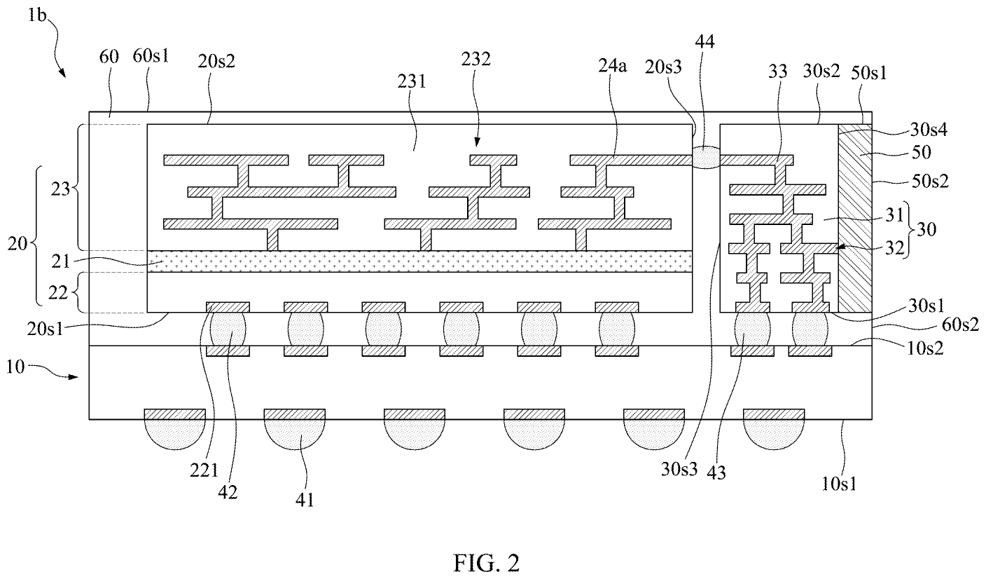

FIG. 2 is a cross-sectional view of an electronic device 1b, in accordance with an embodiment of the present disclosure. The electronic device 1b is similar to the electronic device 1a, with differences therebetween as follows.

In some embodiments, the electronic device 1b may include a heat dissipation element 50. In some embodiments, the heat dissipation element 50 may be disposed on a surface 30s4, opposite to the surface 30s3, of the conductive structure 30. The heat dissipation element 50 may be configured to transmit heat from the electronic device 1b to the environment. The heat dissipation element 50 may include copper (Cu), aluminum (Al) and/or other suitable materials. Although FIG. 2 illustrates that the electronic component 20 and the heat dissipation element 50 are disposed on opposite sides of the conductive structure 30, the heat dissipation element 50 may be disposed at an adjacent side of the surface 30s3 in other embodiments. The heat dissipation element 50 may have a surface 50s1 (or an upper surface) and a surface 50s2 (or a lateral surface) connected to the surface 50s1. In some embodiments, the surface 50s2 of the heat dissipation element 50 may be substantially aligned with the surface 30s2 of the conductive structure 30. In other embodiments, the surface 50s2 of the heat dissipation element 50 and the surface 30s2 of the conductive structure 30 may be located at different levels (or elevations) with respect to the surface 10s2 of the carrier 10.

In some embodiments, the electronic device 1b may include an encapsulant 60. The encapsulant 60 may be disposed on or over the surface 10s2 of the carrier 10. In some embodiments, the encapsulant 60 may encapsulate the electronic component 20. In some embodiments, the encapsulant 60 may encapsulate the conductive structure 30. In some embodiments, the encapsulant 60 may encapsulate the power connector 44. The encapsulant 60 may include a novolac-based resin, an epoxy-based resin, a silicone-based resin, or another suitable material. The encapsulant 60 may include a molding compound, which is formed by a molding technique, such as compression molding, injection molding, or transfer molding. Suitable fillers may also be included, such as powdered SiO₂. The encapsulant 60 may have a surface 60s1 (or an upper surface) and a surface 60s2 (or a lateral surface) connected to the surface 60s1. In some embodiments, the surface 60s2 of the encapsulant 60 may be substantially aligned with the surface 50s2 of the heat dissipation element 50. In some embodiments, the encapsulant 60 may cover the surface 50s1 of the heat dissipation element 50.

In this embodiment, the heat dissipation element 50 may be disposed on the surface 30s4 of the conductive structure 30. Therefore, the thickness of the electronic device 1b may be reduced in comparison with a comparative example where a heat dissipation element is disposed over an interposer or over an electronic component.

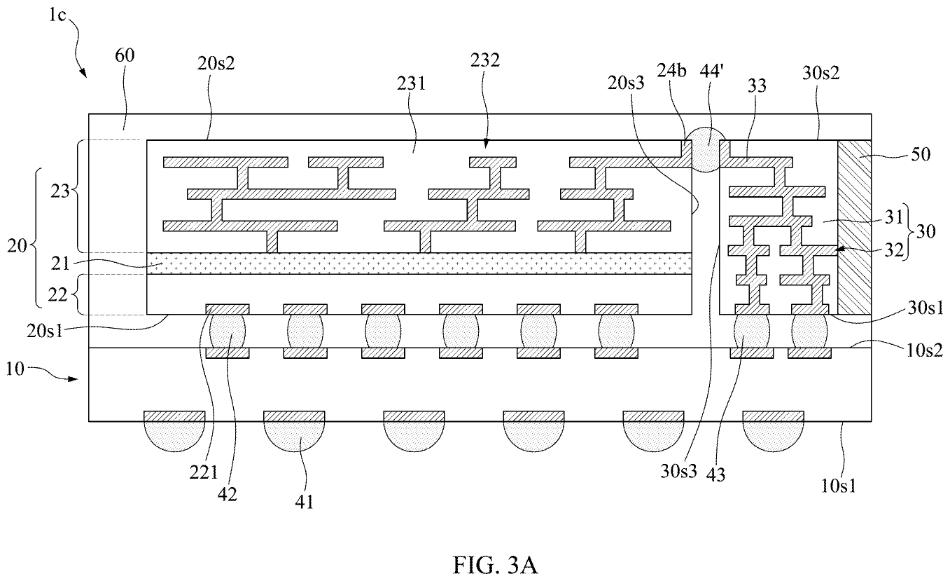

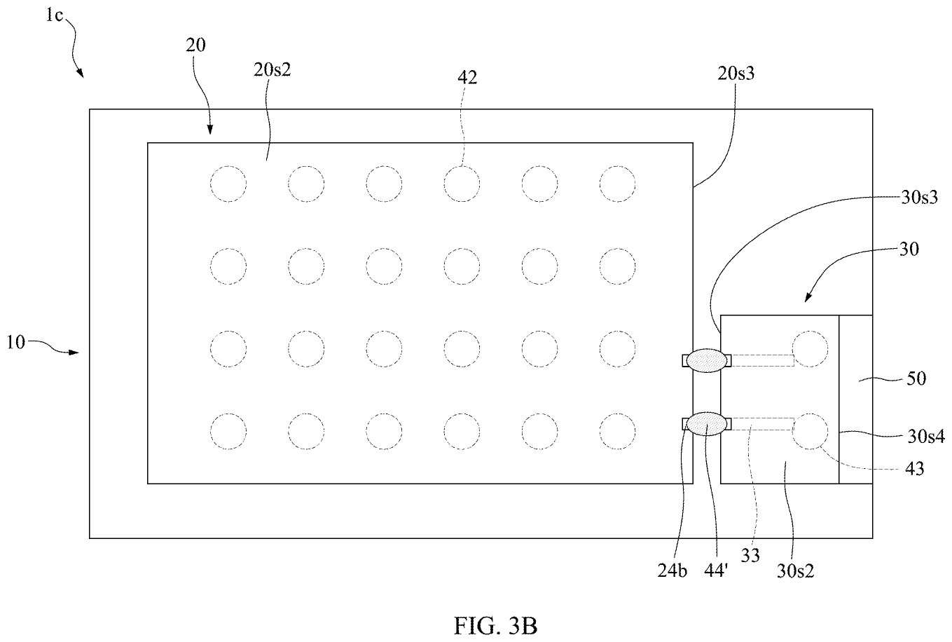

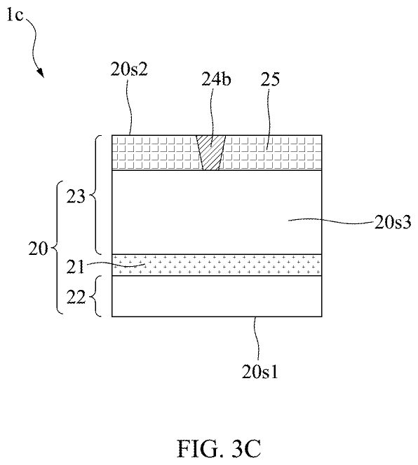

FIG. 3A is a cross-sectional view of an electronic device 1c, in accordance with an embodiment of the present disclosure. The electronic device 1c is similar to the electronic device 1b, with differences therebetween as follows.

In some embodiments, the electronic device 1c may include an electrical connection 24b. In some embodiments, the electrical connection 24b may include a conductive via exposed by the surface 20s3 of the electronic component 20. In some embodiments, the electrical connection 24b may be exposed by the surface 20s2 of the electronic component 20.

The electronic device 1c may include a power connector 44′. In some embodiments, the power connector 44′ may cover the surface 20s2 of the electronic component 20. The power connector 44′ may be in contact with the top (or top surface) of the electrical connection 24b. In some embodiments, the power connector 44′ may cover the surface 30s2 of the conductive structure 30.

FIG. 3B is a top view of the electronic device 1c as shown in FIG. 3A, in accordance with an embodiment of the present disclosure. It should be noted that some elements (e.g., the encapsulant 60) are omitted from FIG. 3B for brevity. In some embodiments, a dimension of the electronic component 20 may be greater than that of the conductive structure 30. For example, the surface area of the surface 20s2 of the electronic component 20 may be greater than that of the surface 30s2 of the conductive structure 30. The length (or width) of the electronic component 20 may be greater than that of the conductive structure 30.

FIG. 3C is a side view of the electronic device 1c as shown in FIG. 3A, in accordance with an embodiment of the present disclosure. In some embodiments, the electrical connection 24b may have a cross-section tapered toward the surface 20s1 of the electronic component 20. The redistribution structure 23 may include a dielectric layer 25 (or an activity layer) which functions as the topmost dielectric layer of the redistribution structure 23. The electrical connection 24b may be surrounded by the dielectric layer 25. The upper surface and the lateral surface of the electrical connection 24b may be exposed by the dielectric layer 25.

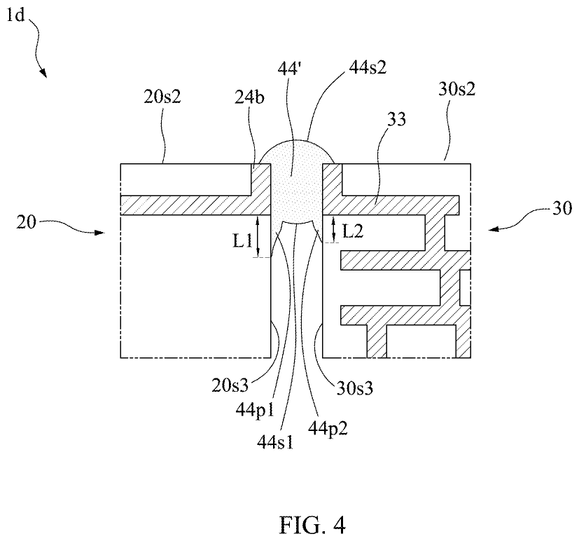

FIG. 4 is a cross-sectional view of an electronic device 1d, in accordance with an embodiment of the present disclosure. The electronic device 1d is similar to the electronic device 1c, with differences therebetween as follows.

The power connector 44′ may have a surface 44s1 (or a lower surface) and a surface 44s2 (or an upper surface) opposite to the surface 44s1. In some embodiments, the surface area of the surface 44s2 may be greater than that of the surface 44s1. In some embodiments, the curvature of the surface 44s1 may be different from that of the surface 44s2. In some embodiments, the power connector 44′ may include a protruded portion 44p1 abutting the surface 20s3 and a protruded portion 44p2 abutting the surface 30s3. Each of the protruded portion 44p1 and protruded portion 44p2 may be protruded from the surface 44s1. In some embodiments, the dimension (e.g., length) L1 of the protruded portion 44p1 may be different from the dimension (e.g., length) L2 of the protruded portion 44p2. In some embodiments, at least a portion of the top (or upper surface) of the electrical connection 24b may be in contact with the power connector 44′. In some embodiments, the power connector 44′ may be protruded from the surface 20s2 of the electronic component 20. In some embodiments, the power connector 44′ may be protruded from the surface 30s2 of the conductive structure 30.

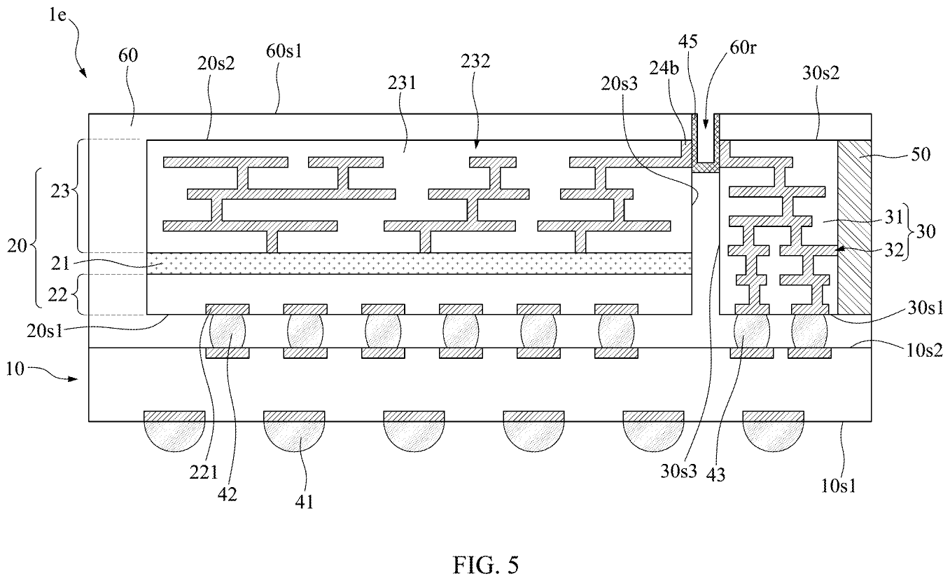

FIG. 5 is a cross-sectional view of an electronic device 1e, in accordance with an embodiment of the present disclosure. The electronic device 1e is similar to the electronic device 1c, with differences therebetween as follows.

In some embodiments, the encapsulant 60 may define a recess 60r (or cavity) recessed from the surface 60s1. The electronic device 1e may include a power connector 45. In some embodiments, the recess 60r of the encapsulant 60 may accommodate the power connector 45. In some embodiments, the power connector 45 may extend from the surface 60s1 of the encapsulant 60. In some embodiments, the power connector 45 may be formed by a sputter technique. In some embodiments, the power connector 45 may include a conductive layer. In some embodiments, the power connector 45 may include a seed layer (not shown) and a conductive material (not shown) formed on the seed layer. The seed layer may include titanium, titanium nitride, or other suitable materials. The conductive material may include copper, silver, aluminum, or other suitable materials.

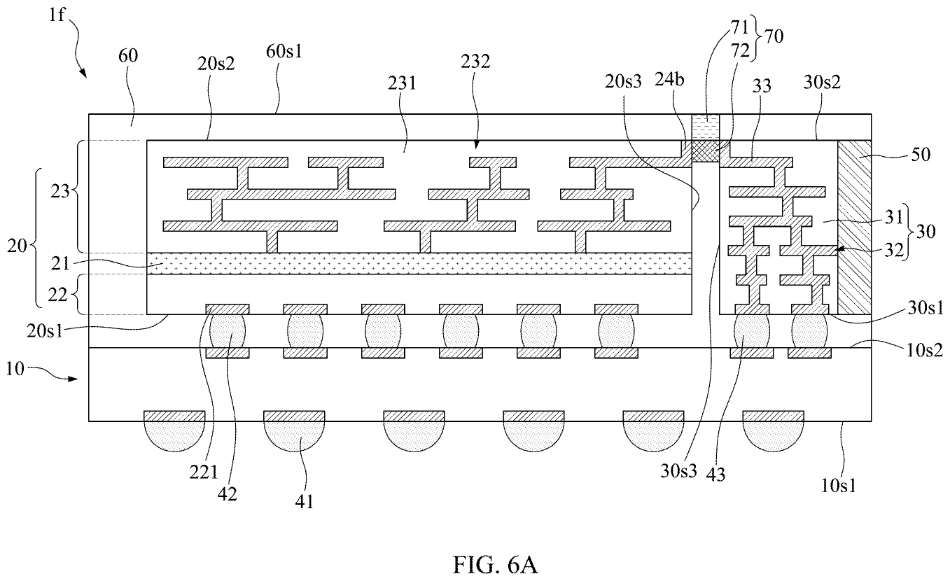

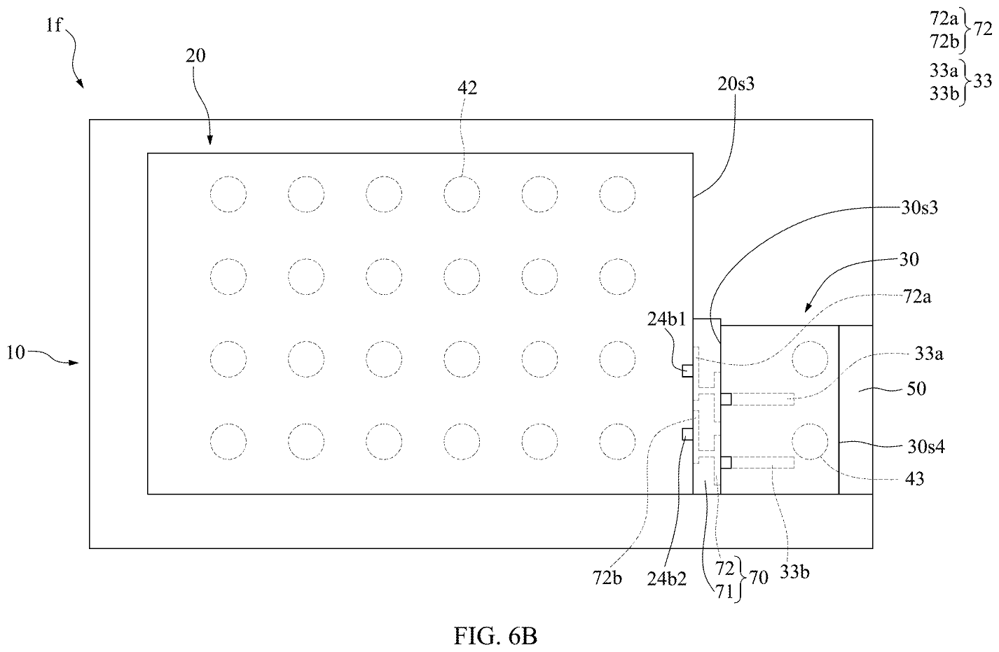

FIG. 6A is a cross-sectional view of an electronic device 1f, in accordance with an embodiment of the present disclosure. The electronic device 1f is similar to the electronic device 1c, with differences therebetween as follows.

In some embodiments, the electronic device 1f may include a power connector 70 disposed between the electronic component 20 and the conductive structure 30. In some embodiments, the power connector 70 may include a redistribution structure which includes a dielectric structure 71 and a conductive layer 72 embedded within the dielectric structure 71. The dielectric structure 71 may be configured to protect the conductive layer 72. In some embodiments, the conductive layer 72 may include at least one conductive trace connecting the electrical connections 24b and 33.

FIG. 6B is a top view of the electronic device 1f as shown in FIG. 6A, in accordance with an embodiment of the present disclosure. In some embodiments, the pattern of the conductive layer 72a may be designed to connect the electrical connections 24b1 and the electrical connection 33a, and the conductive layer 72b may be designed to connect the electrical connections 24b2 and the electrical connection 33b. In some embodiments, the electrical connection 24b may be misaligned with the electrical connection 33. The power connector 70 enhances the flexibility of the layout of the conductive structure 30. In some embodiments, the conductive layers 72a and 72b may be located at different elevations with respect to the carrier 10.

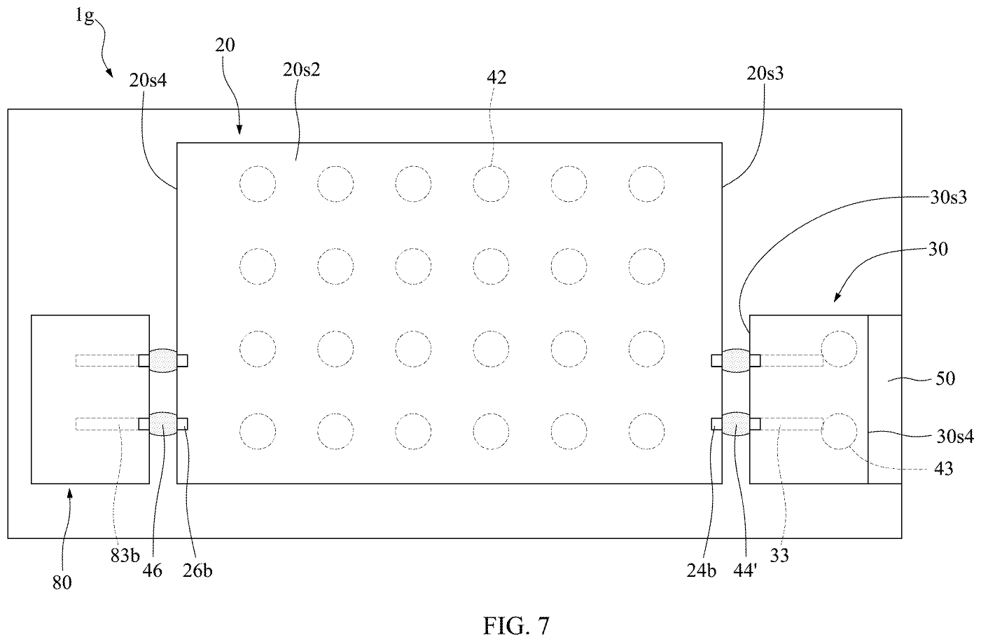

FIG. 7 is a top view of an electronic device 1g, in accordance with an embodiment of the present disclosure. The electronic device 1g is similar to the electronic device 1c, with differences therebetween as follows.

In some embodiments, the electronic device 1g may include a conductive structure 80. In some embodiments, the conductive structure 80 may be configured to receive and/or transmit power to the electronic component 20. The structure and composition of the conductive structure 80 may be substantially the same as or similar to those of the conductive structure 30. The conductive structures 30 and 80 may be configured to provide the different ICs, with different functions, of the electronic component 20 with power. In some embodiments, the power (or voltage) from the conductive structure 30 may be different from that from the conductive structure 80. In some embodiments, the conductive structure 80 may be located at a surface 20s4 opposite to the surface 20s3. In other embodiments, the conductive structure 80 may be located at an adjacent side of the surface 20s3 of the electronic component 20. The conductive structure 80 may include an electrical connection 83b configured to receive and/or transmit power to the electronic component 20. The electrical connection 83b may be substantially aligned with an electrical connection 26b, which is exposed by the surface 20s4, of the electronic component 20.

In some embodiments, the electronic device 1g may include a power connector 46. In some embodiments, the power connector 46 may be configured to electrically connect the electrical connection 83b of the conductive structure 80 and the electrical connection 26b of the electronic component 20. In some embodiments, the power connector 46 may be disposed between the electronic component 20 and the conductive structure 80. In some embodiments, the power connector 46 may include a conductive material. In some embodiments, the power connector 46 may include a solder material (or solder element), such as alloys of gold and tin solder or alloys of silver and tin solder.

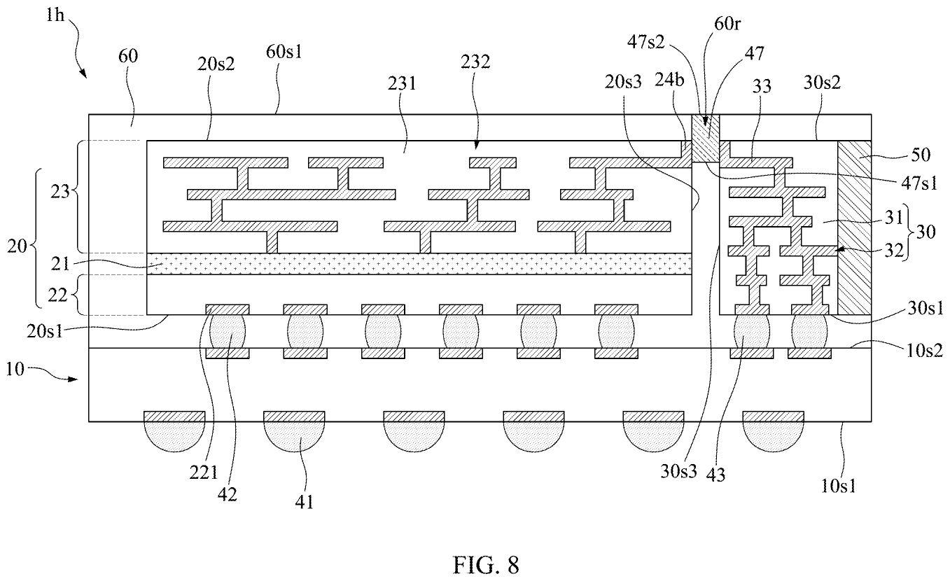

FIG. 8 is a cross-sectional view of an electronic device 1h, in accordance with an embodiment of the present disclosure. The electronic device 1h is similar to the electronic device 1c, with differences therebetween as follows.

In some embodiments, the electronic device 1h may include a power connector 47 located within the recess 60r of the encapsulant 60. In some embodiments, the power connector 47 may be configured to receive and/or transmit power between the electronic component 20 and the conductive structure 30. In some embodiments, the power connector 47 may be disposed between the electronic component 20 and the conductive structure 30. In some embodiments, the power connector 47 may include a solder material (or solder element), such as alloys of gold and tin solder or alloys of silver and tin solder. The power connector 47 may have a surface 47s1 (or a lower surface) and a surface 47s2 (or an upper surface) opposite to the surface 47s1. In some embodiments, the surface 47s1 of the power connector 47 may be a substantially flat surface. In some embodiments, the surface 47s2 of the power connector 47 may be substantially aligned with the surface 60s2 of the encapsulant 60.

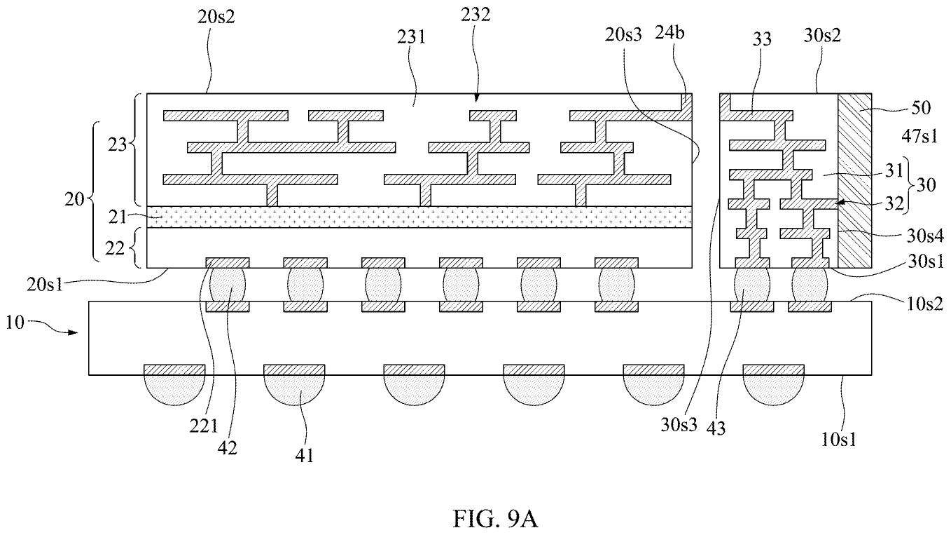

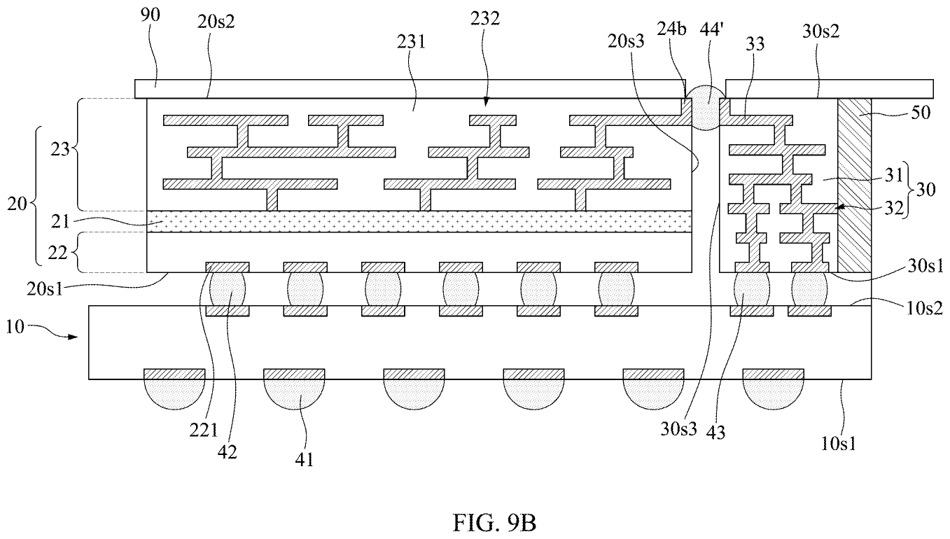

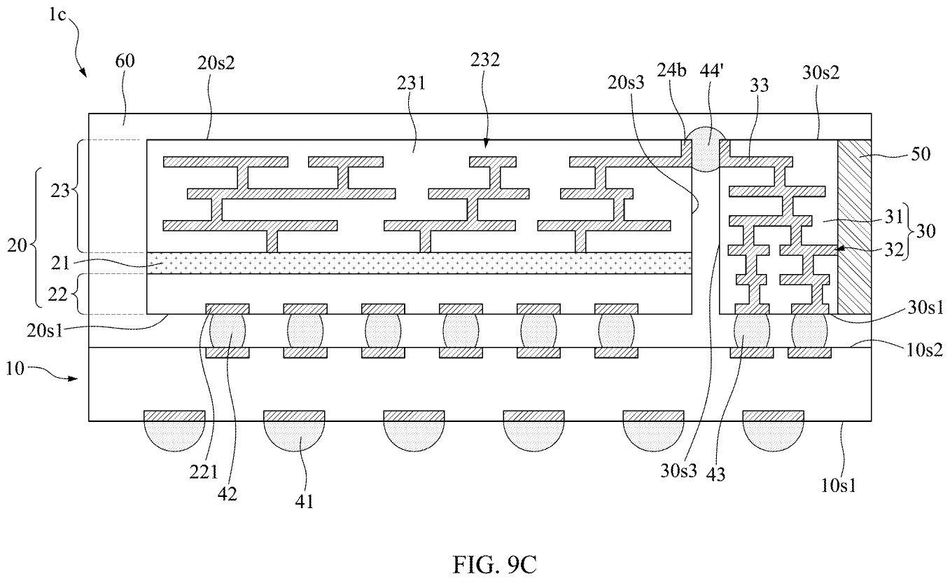

FIG. 9A, FIG. 9B, and FIG. 9C illustrate various stages of an example of a method for manufacturing an electronic device according to some embodiments of the present disclosure.

Referring to FIG. 9A, the carrier 10 may be provided. The electronic component 20 may be attached to the surface 10s2 of the carrier 10 by the electrical connections 42. The conductive structure 30 may be attached to the surface 10s2 of the carrier 10 by the electrical connections 43. The heat dissipation element 50 may be attached to the surface 30s4 of the conductive structure 30. In some embodiments, a portion of the PDN 232 may be formed within the scribe line of a wafer including repeated units, which correspond to multiple electronic components. After a singulation is performed to separate multiple electronic components, the cut PDN 232 may define the electrical connection 24b exposed by the surface 20s3 of the electronic component 20.

Referring to FIG. 9B, a mask 90 may be provided to define a location and/or a pattern of the power connector 44′. The power connector 44′ may be formed between the electronic component 20 and the conductive structure 30. In some embodiments, the power connector 44′ may be formed by a solder printing technique or other suitable techniques. Thus, the profile of the power connector 44′ is different from that of a solder element subjected to a reflow technique.

Referring to FIG. 9C, the encapsulant 60 may be formed to encapsulate the electronic component 20, the conductive structure 30, and the power connector 44′. As a result, an electronic device (e.g., the electronic device 1c as shown in FIG. 3A) may be provided.

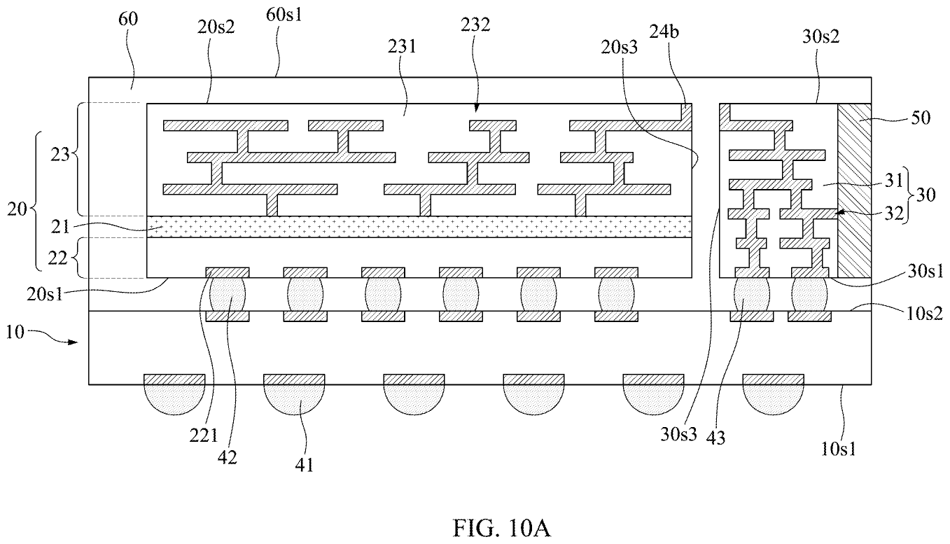

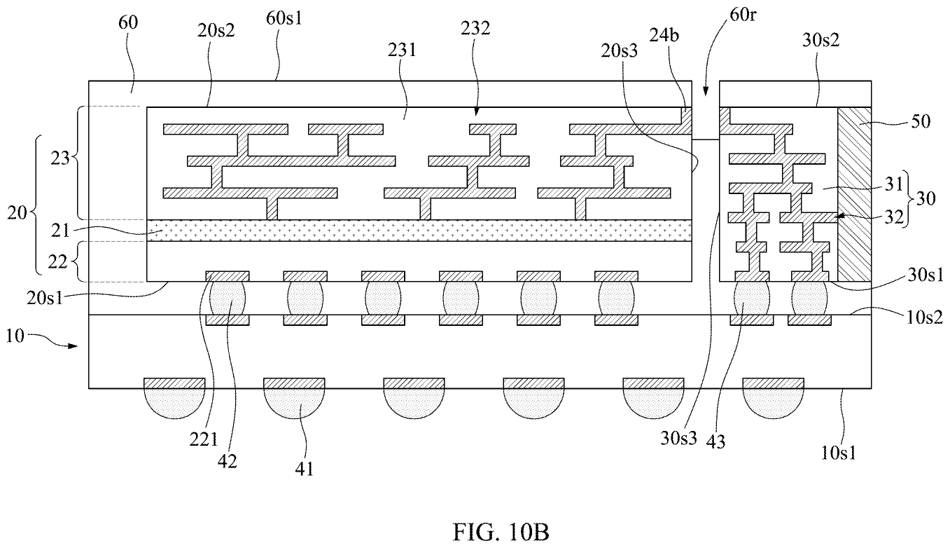

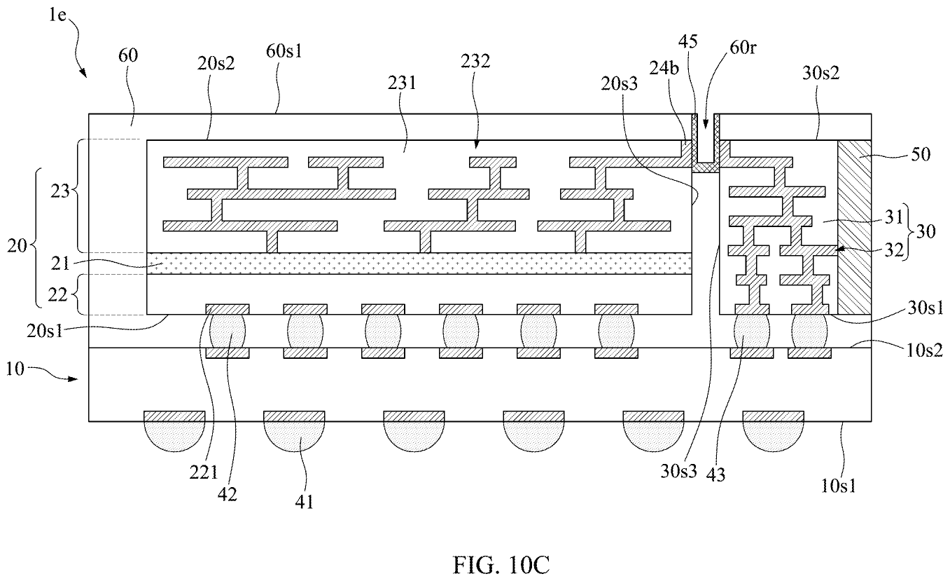

FIG. 10A, FIG. 10B, and FIG. 10C illustrate various stages of an example of a method for manufacturing an electronic device according to some embodiments of the present disclosure. FIG. 10A illustrates a stage subsequent to the stage as shown in FIG. 9A.

Referring to FIG. 10A, the encapsulant 60 may be formed to encapsulate the electronic component 20 and the conductive structure 30.

Referring to FIG. 10B, a portion of the encapsulant 60 may be removed to form the recess 60r. The encapsulant 60 may be formed by a laser drilling technique or other suitable techniques.

Referring to FIG. 10C, a power connector 45 may be formed within the recess 60r. In some embodiments, the power connector 45 may be formed by a sputter technique. As a result, an electronic device (e.g., the electronic device 1e as shown in FIG. 5) may be provided.

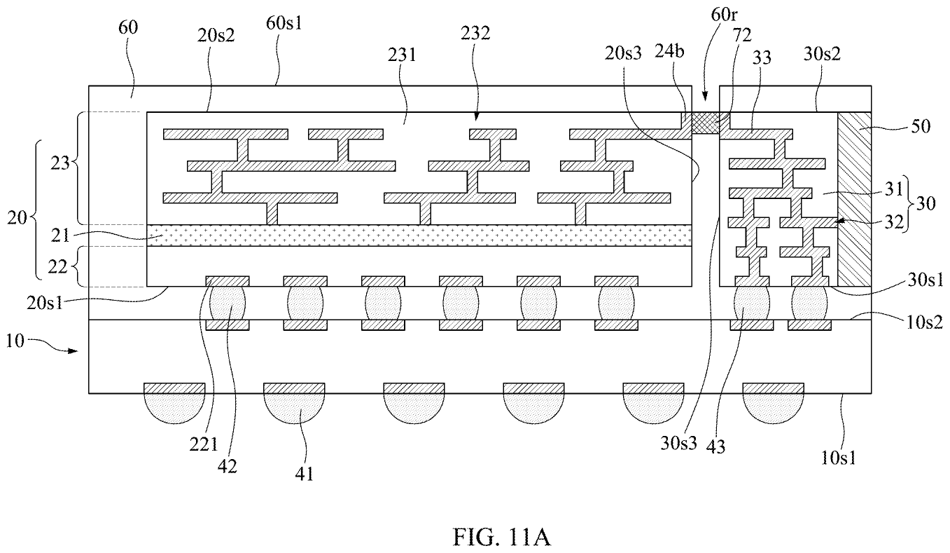

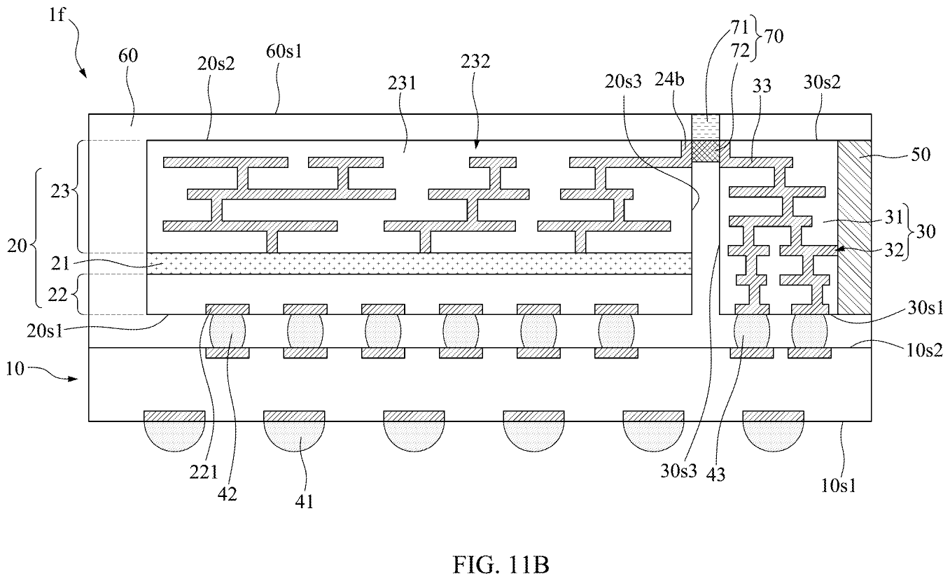

FIG. 11A and FIG. 11B illustrate various stages of an example of a method for manufacturing an electronic device according to some embodiments of the present disclosure. FIG. 11A illustrates a stage subsequent to the stage as shown in FIG. 10B.

Referring to FIG. 11A, the conductive layer 72 may be formed within the recess 60r to electrically connect the electrical connections 24b and 33.

Referring to FIG. 11B, the dielectric structure 71 may be formed to define the power connector 70 between the electronic component 20 and the conductive structure 30. As a result, an electronic device (e.g., the electronic device 1f as shown in FIG. 6A) may be provided.

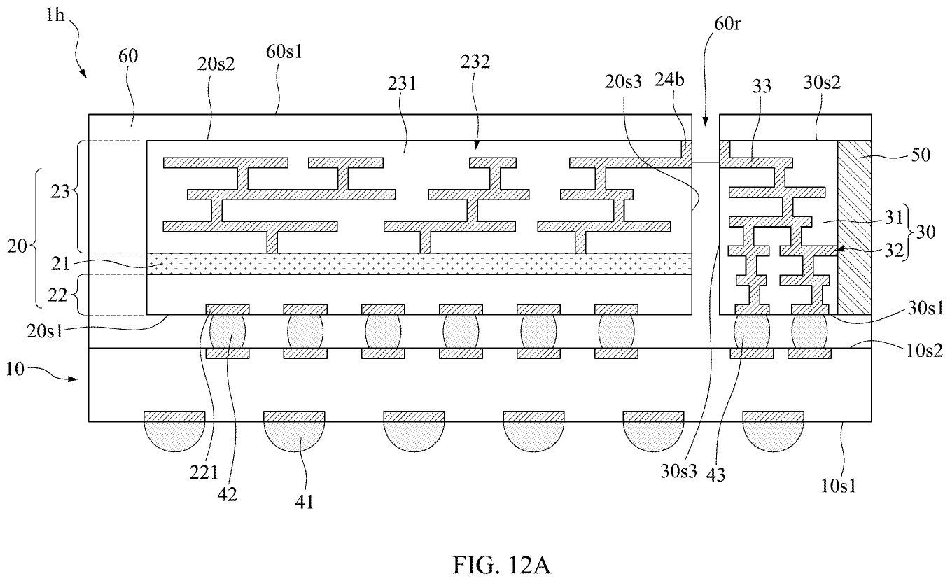

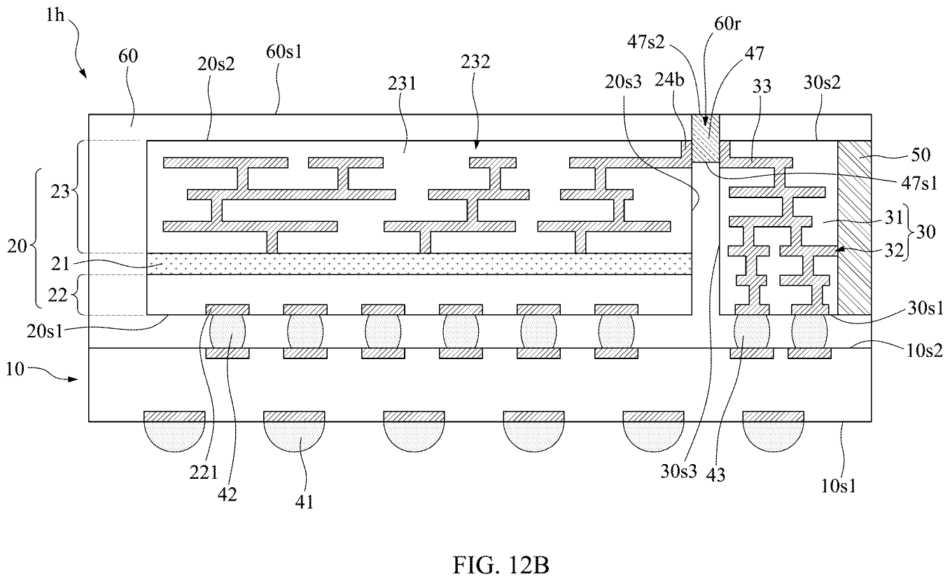

FIG. 12A and FIG. 12B illustrate various stages of an example of a method for manufacturing an electronic device according to some embodiments of the present disclosure. FIG. 12A illustrates a stage subsequent to the stage as shown in FIG. 10A.

Referring to FIG. 12A, a portion of the encapsulant 60 may be removed to form the recess 60r. The recess 60r may be formed by a laser drilling technique or other suitable techniques.

Referring to FIG. 12B, the power connector 47 may be formed within the recess 60r. In some embodiments, the power connector 47 may be formed by a solder printing technique or other suitable techniques. As a result, an electronic device (e.g., the electronic device 1h as shown in FIG. 8) may be provided.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the term “a distance between A and B” may refer to a length from an edge of the A to an edge of the B or to a length from a center of the A to a center of the B.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component configured to laterally receive a power and configured to non-laterally transmit a signal, wherein electronic component comprises an integrated circuit layer configured to receive the power.

2. The electronic device of claim 1, wherein the electronic component has a first lateral surface configured to be passed by the power and a lower surface configured to be passed by the signal.

3. The electronic device of claim 2, wherein the electronic component further comprises a first redistribution structure at a lower side of the integrated circuit layer and configured to transmit the signal as well as a second redistribution structure at an upper side, opposite to the lower side, of the integrated circuit layer and configured to receive the power.

4. The electronic device of claim 3, wherein the second redistribution structure has a first lateral electrical connection, which is configured to receive the power, exposed by the first lateral surface of the electronic component.

5. The electronic device of claim 4, wherein the second redistribution structure has a second lateral electrical connection exposed by a second lateral surface different from the first lateral surface.

6. The electronic device of claim 1, further comprising:
a conductive structure laterally disposed adjacent to the electronic component and configured to transmit the power.

7. The electronic device of claim 6, further comprising:
an electrical contact electrically connecting the electronic component and the conductive structure.

8. The electronic device of claim 7, wherein the electrical contact is disposed between the electronic component and the conductive structure.

9. The electronic device of claim 8, wherein a portion of the electrical contact protrudes over an upper surface of the electronic component and an upper surface of the conductive structure.

10. The electronic device of claim 9, wherein the portion of the electrical contact covers the upper surface of the electronic component and the upper surface of the conductive structure.

11. The electronic device of claim 7, further comprising:
an encapsulant encapsulating the electronic component and the conductive structure, wherein the encapsulant has a cavity disposed between the electronic component and the conductive structure and accommodating the electrical contact.

12. The electronic device of claim 8, wherein the electrical contact comprises portions, each extending downwardly to different elevations relative to an upper surface of the electronic component.

13. The electronic device of claim 6, further comprising:
a carrier supporting the electronic component and the conductive structure, wherein the carrier is configured to provide the conductive structure with the power and configured to receive the signal from the electronic component.

14. An electronic device, comprising:
an integrated circuit component having a lateral surface; and
a power supply element disposed adjacent to the integrated circuit component and having a first lateral surface, wherein the lateral surface of the integrated circuit component and the first lateral surface of the power supply element collectively define a power path.

15. The electronic device of claim 14, wherein the power path is in a gap between the integrated circuit component and the power supply element.

16. The electronic device of claim 14, wherein the integrated circuit component comprises an integrated circuit layer, and an elevation of the power path is higher than that of the integrated circuit layer.

17. The electronic device of claim 16, wherein a portion of the power path passes past the lateral surface of the integrated circuit layer.

18. An electronic device, comprising:
an electronic component having a lateral side, an integrated circuit layer and a power delivery network (PDN) disposed over the integrated circuit layer, wherein a portion of the PDN is exposed by the lateral side and is configured to receive a power.

19. The electronic device of claim 18, wherein the PDN comprises a conductive via exposed by the lateral side of the electronic component.

20. The electronic device of claim 18, further comprising:
a power supply element disposed adjacent to the electronic component; and
an electrical contact configured to bridge the power between the power supply element and the PDN of the electronic component.
